(19) United States
(12) Patent Application Publication
(10) Pub. No.: US 2022/0278142 A1
(43) Pub. Date: Sep. 1, 2022

(54) LIGHT SENSITIVE DEVICE

(71) Applicant: NEXDOT, Romainville (FR)

(72) Inventors: Michele D'AMICO, Romainville (FR); Alexis KUNTZMANN, Clichy La Garenne (FR); Yu-Pu LIN, Versailles (FR); Vladyslav VAKARIN, Palaiseau (FR)

(73) Assignee: NEXDOT, Romainville (FR)

(21) Appl. No.: 17/632,277

(22) PCT Filed: Jul. 31, 2020
(86) PCT No.: PCT/EP2020/071652

§ 371 Date: Feb. 2, 2022

(30) Foreign Application Priority Data
Aug. 5, 2019 (EP) 19190096.8

(51) Int. Cl. H01L 27/146; C09K 11/88; C09K 11/89; C09K 11/02

(52) U.S. Cl. CPC H01L 27/1462; H01L 27/14683; C09K 11/883; C09K 11/892; C09K 11/02

(57) ABSTRACT

A light sensitive device including a substrate and high pass filter semiconductor nanoparticles distributed on the substrate. The substrate includes at least one photosensor, and the semiconductor nanoparticles are high pass filters in UV-visible-NIR light range. The light sensitive device has a density of the semiconductor nanoparticles per surface unit of greater than 5×10⁹ nanoparticles.cm⁻². Also, a process for the manufacture of the light sensitive device, and an image sensor that includes the light sensitive device.

### FIELD OF INVENTION

The present invention pertains to the field of light sensors. In particular, the invention relates to a light sensitive device, a process to prepare a light sensitive devices and image sensor.

### BACKGROUND OF INVENTION

To measure light colour in all its variety, one typically decomposes light into three complementary components, especially red, green and blue. These components allow further restitution of colour by additive synthesis.

A light sensor has to present high selectivity for an accurate colour capture. Usual light sensors use semiconductor materials, typically semiconductor charge-coupled devices to convert light into electric charges. In order to detect separately red, green and blue colours, a structured absorbing layer known as Bayer filter is deposited on semiconductor material. With such filter, neighboring areas known as pixels are defined, each pixel absorbing a part of light arriving on sensor. By appropriate signal treatment, colour components of incoming light are determined.

Bayer filters very often consist of organic dyes deposited by stereolithographic processes. Intrinsically, organic dyes have broad absorption bands which limit selectivity of light sensors. In addition, it is difficult to deposit these dyes on a very accurate pattern, reducing sensibility and resolution of light sensors.

Semiconductor nanoparticles, commonly called “quantum dots”, are known as light absorbing material. Said objects are high-pass filters as they have a broad absorption spectrum over a range of wavelengths from ultra-violet to a well definite wavelength within UV, visible or Near Infra-Red light range. They offer the possibility to absorb all light in a part of UV-visible-NIR spectrum having an energy higher than the bandgap energy of the semiconductive material while not absorbing all light having energy lower than the bandgap energy of the semiconductive material. Very efficient high pass optical filters are thus obtained.

However, distributing such semiconductor nanoparticles on a pattern with well controlled size, i.e. size of nanoparticles deposit and/or size of pattern, is still an unmet challenge.

It is therefore an object of the present invention to provide a light sensitive device having well controlled pattern, which can be used as elementary brick for various light sensors like image sensors (in visible light) or infra-red sensors (for recognition devices).

### SUMMARY

This invention thus relates to a light sensitive device comprising a substrate and semiconductor nanoparticles distributed on the substrate according to a pattern, wherein substrate comprises at least one photosensor, wherein semiconductor nanoparticles are high pass filters in UV-visible-NIR light range, and wherein the light sensitive device comprises a density of semiconductor nanoparticles per surface unit greater than 5×10⁹ nanoparticles.cm⁻².

According to an embodiment, semiconductor nanoparticles are deposited on the substrate with a thickness of less than 10000 nm and more than 100 nm, and the volume fraction of semiconductor nanoparticles in the light sensitive device is ranging from 10% to 90%.

According to an embodiment, semiconductor nanoparticles have a longest dimension less than 1μm.

According to an embodiment, semiconductor nanoparticles are inorganic, preferably semiconductor nanoparticles are semiconductor nanocrystals comprising a material of formula MₓQ_{y}E_{z}A_{w}, wherein: M is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu,

Gd, Tb, Dy, Ho, Er, Tm, Yb, Cs; Q is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs; E is selected from the group consisting of O, S, Se, Te, C, N, P, As, Sb, F, Cl, Br, I; A is selected from the group consisting of O, S, Se, Te, C, N, P, As, Sb, F, Cl, Br, I; and x, y, z and w are independently a rational number from 0 to 5; x, y, z and w are not simultaneously equal to 0; x and y are not simultaneously equal to 0; z and w are not simultaneously equal to 0.

According to an embodiment, semiconductor nanoparticles have a longest dimension greater than 25 nanometers.

According to an embodiment, semiconductor nanoparticles are deposited with their longest dimension substantially aligned in a predetermined direction.

According to an embodiment, nanoparticles are deposited with a thickness of less than 10000 nm and more than 100 nm, preferably less than 3000 nm and more than 200 nm.

According to an embodiment, semiconductor nanoparticles have a cutoff wavelength in near infra-red range.

According to an embodiment, semiconductor nanoparticles are composite nanoparticles comprising absorbent semiconductor nanoparticles encapsulated in a matrix, preferably an inorganic matrix.

According to an embodiment, the pattern is periodic and the repetition unit of the pattern has a smallest dimension of less than 500 micrometers and comprises at least two pixels. In a particular configuration, the pattern is periodic in two dimensions, preferably the pattern is a rectangular lattice or a square lattice. In another particular configuration, semiconductor nanoparticles on the first pixel of the at least two pixels are different from semiconductor nanoparticles on the second pixel of the at least two pixels.

The invention also relates to a first process for the manufacture of a light sensitive device comprising a substrate and semiconductor nanoparticles distributed on the substrate according to a pattern comprising the steps of:
i) Providing an electret film;
ii) Writing a surface electric potential on the electret film according to the pattern;
iii) Bringing the electret film in contact with a colloidal dispersion of semiconductor nanoparticles being high pass filters in UV-visible-NIR light range for a contacting time of less than 15 minutes; and
iv) Transferring film on a photosensor sheet, yielding said substrate; wherein the light sensitive device comprises a density of semiconductor nanoparticles per surface unit greater than 5×10⁹nanoparticles.cm⁻².

The invention also relates to a second process for the manufacture of a light sensitive device comprising a substrate and semiconductor nanoparticles distributed on the substrate according to a pattern, wherein the pattern comprises two sub-patterns comprising the steps of:
i) Providing an electret film;
ii) Writing a surface electric potential on the electret film according to the first sub-pattern;
iii) Bringing the electret film in contact with a colloidal dispersion of semiconductor nanoparticles being high pass filters in UV-visible-NIR light range for a contacting time of less than 15 minutes;
iv) Drying the electret film and semiconductor nanoparticles deposited thereon to form an intermediate structure;
v) Writing a surface electric potential on the intermediate structure according to the second sub-pattern;
vi) Bringing the electret film in contact with a colloidal dispersion of semiconductor nanoparticles being high pass filters in UV-visible-NIR light range and different from those used in step iii) for a contacting time of less than 15 minutes; and
vii) Transferring film on a photosensor sheet, yielding said substrate;
wherein the light sensitive device comprises a density of semiconductor nanoparticles per surface unit greater than 5×10⁹nanoparticles.cm⁻².

The invention also relates to a third process for the manufacture of a light sensitive device comprising a substrate and semiconductor nanoparticles distributed on the substrate according to a pattern comprising the steps of:
i) Providing a film;
ii) Inducing a surface electric potential on the film according to the pattern;
iii) Bringing the film in contact with a colloidal dispersion of semiconductor nanoparticles being high pass filters in UV-visible-NIR light range for a contacting time of less than 15 minutes, while surface electric potential is maintained; and
iv) Transferring film on a photosensor sheet, yielding said substrate;
wherein the light sensitive device comprises a density of semiconductor nanoparticles per surface unit greater than 5×10⁹nanoparticles.cm⁻².

The invention also relates to a fourth process for the manufacture of a light sensitive device comprising a substrate and semiconductor nanoparticles distributed on the substrate according to a pattern, wherein the pattern comprises two sub-patterns comprising the steps of:
i) Providing a film;
ii) Inducing a surface electric potential on the film according to the first sub-pattern;
iii) Bringing the film in contact with a colloidal dispersion of semiconductor nanoparticles being high pass filters in UV-visible-NIR light range for a contacting time of less than 15 minutes, while surface electric potential is maintained;
iv) Drying the film and semiconductor nanoparticles deposited thereon to form an intermediate structure;
v) Inducing a surface electric potential on the intermediate structure according to the second sub-pattern;
vi) Bringing the electret film in contact with a colloidal dispersion of semiconductor nanoparticles being high pass filters in UV-visible-NIR light range and different from those used in step iii) for a contacting time of less than 15 minutes, while surface electric potential is maintained; and
vii) Transferring film on a photosensor sheet, yielding said substrate;
wherein the light sensitive device comprises a density of semiconductor nanoparticles per surface unit greater than 5×10⁹ nanoparticles.cm⁻².

The invention also relates to a fifth process for the manufacture of a light sensitive device comprising a substrate and semiconductor nanoparticles distributed on the substrate according to a pattern comprising the steps of:
i) Providing a film;
ii) Ink-jetting a colloidal dispersion of semiconductor nanoparticles being high pass filters in UV-visible-NIR light range on the film according to the pattern; and
iii) Transferring film on a photosensor sheet, yielding said substrate;
wherein the light sensitive device comprises a density of semiconductor nanoparticles per surface unit greater than 5×10⁹nanoparticles.cm⁻².

The invention also relates to a sixth process for the manufacture of a light sensitive device comprising a substrate and semiconductor nanoparticles distributed on the substrate according to a pattern comprising the steps of:
i) Providing a substrate comprising at least one photosensor; and
ii) Ink-jetting a colloidal dispersion of semiconductor nanoparticles being high pass filters in UV-visible-NIR light range on the substrate according to the pattern;
wherein the light sensitive device comprises a density of semiconductor nanoparticles per surface unit greater than 5×10⁹nanoparticles.cm⁻².

The invention further relates to an image sensor comprising a light sensitive device comprising a substrate and semiconductor nanoparticles distributed on the substrate according to a pattern, wherein substrate comprises at least one photosensor, wherein semiconductor nanoparticles are high pass filters in UV-visible-NIR light range, and wherein the light sensitive device comprises a density of semiconductor nanoparticles per surface unit greater than 5×10⁹nanoparticles.cm⁻².

### DEFINITIONS

In the present invention, the following terms have the following meanings:
“about” is used herein in relation with light wavelength to mean approximately, roughly, around, or in the region of. When the term “about” is used in conjunction with a numerical range, it modifies that range by extending the boundaries above and below the numerical values set forth. In general, the term “about” is used herein to modify a numerical value above and below the stated value by plus or minus 5 percent.
“aspect ratio” is a feature of anisotropic particles. An anisotropic particle has three characteristic dimensions, one of which is the longest and one of which is the shortest. Aspect ratio of an anisotropic particle is the ratio of the longest dimension divided by the shortest dimension. Aspect ratio is necessarily greater than 1. For instance, a nanoparticle of length L=30 nm, width W=20 nm and thickness T=10 nm has an aspect ratio of L/T=3, as shown on FIG. 2. Shape factor is a synonym of aspect ratio.
“blue range” refers to the range of wavelength from 400 nm to 500 nm.
“colloidal” refers to a substance in which particles are dispersed, suspended and do not settle, flocculate or aggregate; or would take a very long time to settle appreciably, but are not soluble in said substance.
“colloidal nanoparticles” refers to nanoparticles that may be dispersed, suspended and which would not settle, flocculate or aggregate; or would take a very long time to settle appreciably in another substance, typically in an aqueous or organic solvent, and which are not soluble in said substance. “Colloidal nanoparticles” does not refer to particles grown on substrate.
“core/shell” refers to heterogeneous nanostructure comprising an inner part: the core, overcoated on its surface, totally or partially, by a film or a layer of at least one atom thick material different from the core: the shell. Core/shell structures are noted as follows: core material/shell material. For instance, a particle comprising a core of CdSe and a shell of ZnS is noted CdSe/ZnS. By extension, core/shell/shell structures are defined as core/first-shell structures overcoated on their surface, totally or partially, by a film or a layer of at least one atom thick material different from the core and/or from the first shell: the second-shell. For instance, a particle comprising a core of CdSe_{0.45}S_{0.55}, a first-shell of Cd_{0.80}Zn_{0.20}S and a second-shell of ZnS is noted CdSe_{0.45}S_{0.55}/Cd_{0.80}Zn_{0.20}S//ZnS.
“electret” refers to a material able to have a non-zero polarization density (i.e. the material contains electric dipole moments) for a long time, without external electric field. Polarization density may be created by injection of electric charges in material, sad charges creating polarization density. In an electret material, dissipation of polarization density is slow (as compared to conductive materials), typically from tens of seconds to tens of minutes. To the purpose of the invention, the stability of polarization should be bigger than 1 minute.
“fluorescent” refers to the property of a material that emits light after being excited by absorption of light. Actually, light absorption drives said material in an excited state, which eventually relaxes by emission of light of lower energy, i.e. of longer wavelength.
“FWHM” refers to Full Width at Half Maximum for a band of emission/absorption of light.
“green range” refers to the range of wavelength from 500 nm to 600 nm.
“high pass filter” refers to an optical filter, i.e. an absorbing filter here, which absorbs all wavelength below a given wavelength known as “cutoff wavelength” and does not absorb all wavelength above said cutoff wavelength. Here, does not absorb means that absorption of optical filter is less than 5%, preferably less than 3%, more preferably less than 1%.
“IR” stands for “Infra-Red” and refers to light of wavelength in the range from 780 nm to 15000 nm.
“LWIR” stands for “Long-Wavelength Infra-Red” and refers to light of wavelength in the range from 8000 nm to 15000 nm.
“MₓE_{z}” refers to a material composed of chemical element M and chemical element E, with a stoichiometry of x elements of M for z elements of E, x and z being independently a decimal number from 0 to 5; x and z not being simultaneously equal to 0. The stoichiometry of MₓE_{z} is not strictly limited to x:z but includes slight variations in composition due to nanometric size of nanoparticles, crystalline face effect and potentially doping. Actually, MₓE_{z} defines material with M content in atomic composition between x-5% and x+5%; with E content in atomic composition between z-5% and z+5%; and with atomic composition of compounds different from M or E from 0.001% to 5%. Same principle applies for materials composed of three of four chemical elements.
“MWIR” stands for “Mid-Wavelength Infra-Red” and refers to light of wavelength in the range from 3000 nm to 8000 nm.
“nanoparticle” refers to a particle having at least one dimension in the 0.1 to 100 nanometers range. Nanoparticles may have any shape. A nanoparticle may be a single particle or an aggregate of several single particles or a composite particle comprising single particles dispersed in a matrix. Single particles may be crystalline. Single particles may have a core/shell or plate/crown structure.

“nanoplatelet” refers to a nanoparticle having a 2D-shape, i.e. having one dimension smaller than the two others; said smaller dimension ranging from 0.1 to 100 nanometers. In the sense of the present invention, the smallest dimension (hereafter referred to as the thickness) is smaller than the other two dimensions (hereafter referred to as the length and the width) by a factor (aspect ratio) of at least 1.5. In some cases, structure of nanoplatelets is defined with the exact number of atomic monolayers and noted “ME n monolayers”, where a monolayer is one layer of anionic compounds (−) and one layer of cationic compounds (+). In addition, external layers of nanoplatelets are always of cationic compounds (+). For instance, “CdSe_{0.85}S_{0.15} 4 monolayers” defines nanoplatelets formed of 9 layers: 5 layers of cationic compounds (Cd) and 4 layers of anionic compounds (mixture of 85% Se and 15% S in atomic composition) disposed in alternance (+)(−)(+)(−)(+)(−)(+)(−)(+) having globally a stoichiometric composition of CdSe_{0.85}S_{0.15}. The number of monolayers actually defines the exact thickness of nanoplatelets.
“NIR” stands for “Near Infra-Red” and refers to light of wavelength in the range from 780 nm to 1400 nm.
“optically transparent” refers to a material that absorbs less than 10%, 5%, 1%, or 0.5% of light at wavelengths between 200 nm and 2500 nm, between 200 nm and 2000 nm, between 200 nm and 1500 nm, between 200 nm and 1000 nm, between 200 nm and 800 nm, between 400 nm and 700 nm, between 400 nm and 600 nm, or between 400 nm and 470 nm.
“periodic pattern” refers to an organization of a surface on which a geometric element is repeated regularly, the length of repetition being the period. Lattices are specific periodic patterns.
“photosensor” refers to a set up able to convert a light signal, i.e. an incident photon, into an electric signal, i.e. one or several electrons. Typical photosensors are made of semi-conductive materials. They may be photodiodes or charge-coupled devices (CCD).
“pixel” refers to a geometrical area in a repetition unit. By extension, if nanoparticles are on said area and form a volume of material: this volume is also a pixel. In particular, a pixel may be a sub-unit of a repetition unit.
“red range” refers to the range of wavelength from 600 nm to 780 nm.
“repetition unit” refers to a single geometric element that is repeated in a periodic pattern.
“SWIR” stands for “Short-Wavelength Infra-Red” and refers to light of wavelength in the range from 1400 nm to 3000 nm.
“UV” refers to light of wavelength in the range from 10 nm to 380 nm. In particular, UVA refers to the sub-range of UV from 315 nm to 380 nm.
“UVA-Visible-NIR” refers to light of wavelength in the range from 315 nm to 1400 nm.
“Visible” refers to light of wavelength in the range from 380 nm to 780 nm.

### DETAILED DESCRIPTION

The following detailed description will be better understood when read in conjunction with the drawings. For the purpose of illustrating, the light sensor is shown in the preferred embodiments. It should be understood, however that the application is not limited to the precise arrangements, structures, features, embodiments, and aspect shown. The drawings are not drawn to scale and are not intended to limit the scope of the claims to the embodiments depicted. Accordingly, it should be understood that where features mentioned in the appended claims are followed by reference signs, such signs are included solely for the purpose of enhancing the intelligibility of the claims and are in no way limiting on the scope of the claims.

This invention relates to a light sensitive device comprising a substrate and semiconductor nanoparticles distributed on the substrate according to a pattern. In the invention, substrate comprises at least one photosensor, allowing to capture signal corresponding to light incoming on the light sensitive device. The photosensor may be on the surface of the substrate or covered by a layer, preferably said layer is an electret material. The light sensitive device comprises a density of semiconductor nanoparticles per surface unit greater than 5×10⁹ nanoparticles.cm⁻², preferably greater than 7×10⁹ nanoparticles.cm⁻², more preferably greater than 1×10¹⁰ nanoparticles.cm⁻², most preferably greater than 1×10¹² nanoparticles.cm⁻², even most preferably greater than 5×10¹⁴ nanoparticles.cm⁻². The density of semiconductor nanoparticles per surface unit in a pixel refers to the number of semiconductor nanoparticles per volume unit in a pixel multiplied by the thickness of the layer of semiconductor nanoparticles on said pixel. A high density of semiconductor nanoparticles is preferred because it allows a close contact between semiconductor nanoparticles, increasing the conductivity of the film. A high density of semiconductor nanoparticles is preferred also because the film is more uniform, compact and without cracks. A high density of semiconductor nanoparticles is also preferred as it allows a high EQE (External Quantum Efficiency), in particular an EQE higher than 5%, preferably higher than 10%, more preferably higher than 20%. Indeed, at similar thickness, a high density film has a greater absorbance cross section and thus a bigger EQE.

One embodiment of the light sensitive device is illustrated in FIG. 1.

In another embodiment, a pixel comprises at least 3×10¹⁴ nanoparticles.cm⁻³, preferably at least 5×10¹⁴ nanoparticles.cm⁻³, more preferably at least 5×10¹⁷ nanoparticles.cm⁻³, most preferably at least 1×10²⁰ nanoparticles.cm⁻³.

In this embodiment, semiconductor nanoparticles on the substrate form layers with a thickness of less than 10000 nm and more than 100 nm, i.e. semiconductor nanoparticles are deposited on the substrate with a thickness of less than 3000 nm and more than 200 nm, and the volume fraction of semiconductor nanoparticles in the light sensitive device is ranging from 10% to 90%, preferably from 20% to 90%, more preferably from 30% to 90%, most preferably from 50% to 90%.

In this embodiment, semiconductor nanoparticles have a longest dimension less than 1 μm, preferably less than 800 nm, more preferably less than 500 nm, most preferably less than 100 nm.

In a particular embodiment, the repetition unit of the pattern comprises at least one pixel, and said pixel comprises a density of semiconductor nanoparticles per surface unit greater than 5×10⁹ nanoparticles.cm⁻², preferably greater than 7×10⁹ nanoparticles.cm⁻², more preferably greater than 1×10¹⁰ nanoparticles.cm⁻², most preferably greater than 1×10¹² nanoparticles.cm⁻², even most preferably greater than 5×10¹⁴ nanoparticles.cm⁻².

Suitable electret material may be selected from polymers, for example: Fluorinated Ethylene Propylene (FEP), Polytetrafluoroethylene (PTFE), Polyethylene (PE), Polycarbonate (PC), Polypropylene (PP), Poly Vinylchloride (PVC), Polyethylene Terephtalate (PET), Polyimide (PI), Polymethyl Methacrylate (PMMA), Polyvinyl fluoride (PVF), Polyvinylidene Fluoride (PVDF), Polydimethylsiloxane (PDMS), Ethylene Vinyl Acetate (EVA), Cyclic Olefin Copolymers (COC), Polyparaxylylène (PPX), Fluorinated parylenes and fluorinated polymers in amorphous form.

Other suitable electret materials may be selected from inorganic materials, for example: Silicon Oxide (SiO₂), Silicon Nitride (Si₃N₄), Aluminium oxide (Al₂O₃) or other doped mineral glass with known dopant atoms (as example Na, S, Se, B).

For instance, a layer of Silicon, optionally doped, with a thin layer of 100 nm of polymethylmethacrylate polymer (PMMA) is suitable as substrate.

In another embodiment, substrate is a soft material, for instance a non-conductive polymeric material, preferably an electret material, configured to be transferred on a semi-conductive or conductive support. By transferred, it is meant any method yielding a structure comprising said soft material on the semi-conductive or conductive support. Transfer may be direct, without any material between substrate and support: this is a direct contact between the substrate and the support. Transfer may use an adhesive between substrate and support, preferably a conductive adhesive. Transfer may use an intermediate carrier. This embodiment enables production of large pieces of substrate which may be stored for some time before being cut on demand and reported on semi-conductive or conductive supports.

In this embodiment, a preferred substrate is an array of photosensors under a layer of PMMA having a thickness between 100 nm and 500 nm.

According to one embodiment, semiconductor nanoparticles have an aspect ratio greater than 1.5. In some embodiments, semiconductor nanoparticles have an aspect ratio greater than 1.5, 2, 2.5, 3, 3.5, 4, 4.5, 5, 6, 7, 8, 9, 10, 15, 20. Semiconductor nanoparticles may have an ovoid shape, a discoidal shape, a cylindrical shape, a faceted shape, a hexagonal shape, a triangular shape, or a platelet shape. The semiconductor nanoparticles may have a 1D shape (cylindrical shape) or a 2D shape (platelet shape).

According to one embodiment, semiconductor nanoparticles may have spherical shape such as for example quantum dots or composite particles (described hereafter), i.e. semiconductor nanoparticles may have a 3D shape.

In the invention, semiconductor nanoparticles are high pass filters in UV-visible-NIR light range. Such absorption spectrum enables a more precise characterization of light incoming on the light sensitive device, yielding an improved accuracy of measure. In some cases, absorbent nanoparticles are fluorescent nanoparticles. In the invention, fluorescence is not desired because fluoresced light would be captured by photosensor and yield erroneous measurements. In a particular embodiment, semiconductor nanoparticles are not fluorescent. In another particular embodiment, semiconductor nanoparticles are modified with quenchers or specific surface treatments to avoid light fluorescence.

Indeed, with such high pass filters, light incoming on photosensors may be chopped in several wavelength band corresponding to colour components of light. For instance, a first photosensor may receive incoming light without filter, i.e. over the whole range of detection of the sensor, for instance from 380 nm to 780 nm for visible light. So as to avoid signal related to UV-A light, a specific UV filter may be applied over this sensor. UV-A absorbing substrates may be selected in the light sensitive device of the invention so as to provide with UV-A filtering over photosensors which are not located below semiconductor nanoparticles.

Then, a second photosensor may receive incoming light through a high pass filter with cutoff wavelength of 500 nm. Difference of signal from first photosensor and second photosensor is a direct measure of the blue component of incoming light. With a third photosensor having a cutoff wavelength of 600 nm, the green component of incoming light may be deduced from signal difference between second and third photosensor. An appropriate selection of cutoff wavelength allows for decomposition of incoming light in colour component, usually three, i.e. blue, green and red, eventually more than three, in particular to include an Infra-Red component of incoming light.

According to an embodiment, semiconductor nanoparticles are inorganic, in particular, semiconductor nanoparticles may be semiconductor nanocrystals comprising a material of formula

MₓQ_{y}E_{z}A_{w} (I)

wherein:

M is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs;

Q is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs;

E is selected from the group consisting of O, S, Se, Te, C, N, P, As, Sb, F, Cl, Br, I;

A is selected from the group consisting of O, S, Se, Te, C, N, P, As, Sb, F, Cl, Br, I; and x, y, z and w are independently a rational number from 0 to 5; x, y, z and w are not simultaneously equal to 0; x and y are not simultaneously equal to 0; z and w are not simultaneously equal to 0. Preferably, semiconductor nanoparticles are so-called quantum dots, i.e. semiconductor nanoparticles having one of their dimensions lower than the Bohr radius of electron-hole pair in the material.

Herein, the formulas MₓQ_{y}E_{z}A_{w}(I) and MₓN_{y}E_{z}A_{w} can be used interchangeably (wherein Q or N is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs).

In one embodiment, semiconductor nanoparticles do not comprise InGaN/GaN.

In one embodiment, semiconductor nanoparticles comprise a semiconductor material selected from the group consisting of group IV, group IIA-VIA, group IIIA-VIA, group IA-IIIA-VIA, group IIA-VA, group IVA-VIA, group VIB-VIA, group VB-VIA, group IVB-VIA or mixture thereof.

In a specific configuration of this embodiment, semiconductor nanocrystals have a homostructure. By homostructure, it is meant that each particle is homogenous and has the same local composition in all its volume. In other words, each particle is a core particle without a shell.

In a specific configuration of this embodiment, semiconductor nanocrystals have a core/shell structure. The core comprises a material of formula MₓQ_{y}E_{z}A_{w} as defined above. The shell comprises a material different from core of formula MₓQ_{y}E_{z}A_{w} as defined above, such as a material of formula

M′_{x′}Q′_{y′}E′_{z′}A′_{w′} (II)

wherein: M′ is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs;

Q′ is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs;

E′ is selected from the group consisting of O, S, Se, Te, C, N, P, As, Sb, F, Cl, Br, I;

A′ is selected from the group consisting of O, S, Se, Te, C, N, P, As, Sb, F, Cl, Br, I; and x′, y′, z′ and w are independently a decimal number from 0 to 5; x′, y′, z′ and w′ are not simultaneously equal to 0; x′ and y′ are not simultaneously equal to 0; z′ and w′ may not be simultaneously equal to 0.

In a more specific configuration of this embodiment, semiconductor nanocrystals have a core/first-shell/second-shell structure (i.e. core/shell/shell structure). The core comprises a material of formula MₓQ_{y}E_{z}A_{w} as defined above. The first-shell comprises a material different from core of formula MₓQ_{y}E_{z}A_{w} as defined above. The second-shell is deposited partially or totally on the first-shell with the same features or different features than the first-shell, such as for example same or different thickness. The material of second-shell is different from the material of the first shell and/or of the material of the core. By analogy, structures with three or four shells may be prepared.

In a specific configuration of this embodiment, semiconductor nanocrystals have a core/crown structure. The embodiments concerning shells apply mutatis mutandis to crowns in terms of composition, thickness, properties, number of layers of material.

In a configuration of this embodiment, semiconductor nanoparticles are colloidal nanoparticles.

In a configuration of this embodiment, semiconductor nanoparticles are electrically neutral. With electrically neutral semiconductor nanoparticles, it is easier to manage deposition on substrate, especially when deposition is driven by electrical polarization.

In a configuration of this embodiment, semiconductor nanoparticles are selected from CdSe 4 monolayers, CdTe 3 monolayers, CdSeₓS₍₁₋ₓ₎ 4 monolayers, CdSeₓS₍₁₋ₓ₎ 5 monolayers, CdₓZn₍₁₋ₓ₎S 4 monolayers, CdₓZn₍₁₋ₓ₎S 5 monolayers, CdSeₓS₍₁₋ₓ₎/ZnS 3 monolayers, CdSeₓS₍₁₋ₓ₎/ZnS 4 monolayers, CdSeₓS₍₁₋ₓ₎/ZnS 5 monolayers, CdSeₓS₍₁₋ₓ₎/ZnSe 3 monolayers, CdSeₓS₍₁₋ₓ₎/ZnSe 4 monolayers, CdSeₓS₍₁₋ₓ₎/ZnSe 5 monolayers, CdSeₓS₍₁₋ₓ₎/Cd_{y}Zn_{(1-y)}S 3 monolayers, CdSeₓS₍₁₋ₓ₎/Cd_{y}Zn_{(1-y)}S, 4 monolayers, CdSeₓS₍₁₋ₓ₎/Cd_{y}Zn_{(1-y)}nS 5 monolayers, InP/ZnS, InP/CdₓZn₍₁₋ₓ₎/ZnS, InP/ZnSe/ZnS, InP/CdₓZn₍₁₋ₓ₎S/ZnS, InP/ZnSe/ZnS, InP/ZnSeₓS₍₁₋ₓ₎/ZnS, InP/CdₓZn₍₁₋ₓ₎S/ZnSe, InP/ZnSe, InP/CdₓZn₍₁₋ₓ₎Se, InP/CdₓZn₍₁₋ₓ₎Se/ZnS, InP/ZnSeₓS₍₁₋ₓ₎ where x, y and z are rational numbers between 0 (excluded) and 1 (excluded), and have a cutoff wavelength about 500 nm which is the limit between blue range and green range. Suitable semiconductor nanoparticles are CdSe_{0.85}S_{0.15} 4 monolayers with a thickness of 1.2 nm and lateral dimensions of about 25 nm and 10 nm.

In a configuration of this embodiment, semiconductor nanoparticles are selected from CdSe 7 monolayers, CdSe/CdTe 7 monolayers type core/crown, CdSeₓS₍₁₋ₓ₎ 4 monolayers, CdSeₓS₍₁₋ₓ₎ 5 monolayers, CdSeₓS₍₁₋ₓ₎/ZnS 4 monolayers, CdSeₓS₍₁₋ₓ₎/ZnS 5 monolayers, CdSeₓS₍₁₋ₓ₎/ZnSe 4 monolayers, CdSeₓS₍₁₋ₓ₎/ZnSe 5 monolayers, CdSeₓS₍₁₋ₓ₎/Cd_{y}Zn_{(1-y)}S 4 monolayers, CdSeₓS₍₁₋ₓ₎/Cd_{y}Zn_{(1-y)}nS 5 monolayers, CdSeₓS₍₁₋ₓ₎/CdS 4 monolayers, CdSeₓS₍₁₋ₓ₎/CdS 5 monolayers, InP/ZnS, InP/CdₓZn₍₁₋ₓ₎S, InP/ZnSe/ZnS, InP/CdₓZn₍₁₋ₓ₎S/ZnS, InP/ZnSe/ZnS, InP/ZnSeₓS₍₁₋ₓ₎/ZnS, InP/CdₓZn₍₁₋ₓ₎S/ZnSe, InP/ZnSe, InP/CdₓZn₍₁₋ₓ₎Se, InP/CdₓZn₍₁₋ₓ₎Se/ZnS, InP/ZnSeₓS₍₁₋ₓ₎ where x, y and z are rational numbers between 0 (excluded) and 1 (excluded), and have a cutoff wavelength about 600 nm which is the limit between green range and red range. Suitable semiconductor nanoparticles are CdSe_{0.80}S_{0.20}/CdS 4 monolayers with a thickness of 5.2 nm (core thickness: 1.2 nm core corresponding to 4 monolayers and shell thickness: 2 nm shell) and lateral dimensions of about 27nm and 12 nm.

In a configuration of this embodiment, semiconductor nanoparticles are selected from PbS, PbSe, PbTe, PbS/CdS, PbS/ZnS, PbS/CdₓZn₍₁₋ₓ₎S, PbS/CdSe, PbS/ZnSe, PbSe/CdS, PbSe/ZnS, PbSe/CdₓZn₍₁₋ₓ₎S, PbSe/CdSe, PbSe/ZnSe, PbTe/CdS, PbTe/ZnS, PbTe/CdₓZn₍₁₋ₓ₎S, PbTe/CdSe, PbTe/ZnSe, HgSe, HgS, HgTe, AhSe, AgS, HgTe, CuInS₂, CuInSe₂ where x, y and z are rational numbers between 0 (excluded) and 1 (excluded), and have a cutoff wavelength about 780 nm which is the limit between red range and NIR range. Suitable semiconductor nanoparticles are HgTe 3 monolayers with a thickness of 1.1 nm and lateral dimensions of about 200 nm and 100 nm.

According to an embodiment, semiconductor nanoparticles have a longest dimension greater than 25 nanometer, preferably greater than 35 nm, more preferably greater than 50 nm. Actually, a size larger than 25 nm along the longest dimension is favorable for deposition of semiconductor nanoparticles on substrate, in particular under di-electrophoretic conditions, in which attraction forces are more efficient for large semiconductor nanoparticles.

Besides, the association of anisotropy and a size larger than 25 nm along the longest dimension is favorable for deposition of semiconductor nanoparticles on substrate, in particular under di-electrophoretic conditions, in which electro-rotation phenomenon takes place, and more particularly for deposition in an oriented manner.

In a specific aspect of this embodiment, semiconductor nanoparticles are on the substrate with their longest dimension substantially aligned in a predetermined direction. Such orientation of semiconductor nanoparticles allows for compact deposition, which has two advantages. First, thickness of deposit is reduced for a same quantity of semiconductor nanoparticles deposited and a thin deposit is desirable for manufacturing reasons. Second, compact deposit avoids that light incoming on a light sensitive device can go through semiconductor nanoparticles without being absorbed. Indeed, with a compact deposit, one can expect an improved absorption and an improved sensitivity of sensor. In this embodiment, “substantially aligned in a predetermined direction” means that at least 50% of the nanoparticles are aligned in a predetermined direction, preferably at least 60% of the nanoparticles are aligned in a predetermined direction, more preferably at least 70% of the nanoparticles are aligned in a predetermined direction, most preferably at least 90% of the nanoparticles are aligned in a predetermined direction.

According to an embodiment, semiconductor nanoparticles are deposited with a thickness of less than 10000 nm and more than 100 nm, preferably less than 3000 nm and more than 200 nm. Indeed, to avoid that light emitted by primary light source can go through semiconductor nanoparticles without being absorbed, inventors identified that a thickness of more than 100 nm is preferred.

According to an embodiment, semiconductor nanoparticles have a cutoff wavelength in near infra-red range (NIR). Semiconductor nanoparticles with broad absorption band in UV and visible light but allowing NIR light to pass through are desirable for use with various devices using infra-red sources for recognition purposes. Typically, an infra-red light emitting device, such as an infra-red LED, is used to illuminate an object to be recognized. Infra-red light is reflected by said object and an infra-red sensor captures reflected light and scattered light. So as to avoid noise, a broad absorption band corresponding to all light having wavelengths shorter than band of infra-red light emitting device is particularly suitable. Devices for recognition purposes may be eye-trackers, movement detectors, face identification systems, night vision, object identification, distance sensor, LiDAR, autonomous vehicles.

According to an embodiment, semiconductor nanoparticles are composite nanoparticles comprising absorbent semiconductor nanoparticles (10) encapsulated in a matrix (20) as shown on FIG. 3. Composite particles may be anisotropic or isotropic. Composite nanoparticles have two advantages. As their size is larger than single absorbent semiconductor nanoparticles, di-electrophoretic forces are more efficient and deposition is quicker than for single absorbent semiconductor nanoparticles. In addition, composite nanoparticles allow for deposition of thicker layers, up to micrometer scale. Last, matrix may be selected to be metastable. In a particular embodiment, composite nanoparticles are metastable. By metastable, it is meant that composite is stable for some time, typically during deposition of nanoparticles on the substrate. But, in a later stage, specific external conditions such as heat, irradiation, ultrasound, pH change or solvent change may be imposed to composite nanoparticles and lead to a degradation of matrix and release of absorbent semiconductor nanoparticles. Metastable composite nanoparticles yield an improved deposition due to size of composite but without diluting absorbent semiconductor nanoparticles in an inert matrix.

In a specific embodiment, absorbent semiconductor nanoparticles (10) are nanoparticles having an aspect ratio greater than 1.5, such as nanoplatelets described above, or nanoparticles having an aspect ratio of 1 such as quantum dots as described above.

In another specific embodiment, absorbent semiconductor nanoparticles (10) are semiconductor nanoparticles whose aspect ratio is less than 1.5. By encapsulation in a matrix (20), said absorbent semiconductor nanoparticles may be manipulated as semiconductor nanoparticles having aspect ratio greater than 1.5 nanometers with advantages of the invention already described.

In a configuration of this embodiment, absorbent semiconductor nanoparticles are semiconductor nanoparticles as described above.

In a configuration of this embodiment, matrix (20) is optically transparent, i.e. matrix (20) is optically transparent in the blue range, in the green range and/or in the red range.

In a configuration of this embodiment, matrix (20) is selected from SiO₂, Al₂O₃, TiO₂, ZrO₂, ZnO, MgO, SnO₂, Nb₂O₅, CeO₂, BeO, IrO₂, CaO, Sc₂O₃, NiO, Na₂O, BaO, K₂O, PbO, Ag₂O, V₂O₅, TeO₂, MnO, B₂O₃, P₂O₅, P₂O₃, P₄O₇, P₄O₈, P₄O₆, PO, GeO₂, As₂O₃, Fe₂O₃, Fe₃O₄, Ta₂O₅, Li₂O, SrO, Y₂O₃, HfO₂, WO₂, MoO₂, Cr₂O₃, Tc₂O₇, ReO₂, RuO₂, Co₃O₄, OsO, RhO₂, Rh₂O₃, PtO, PdO, CuO, Cu₂O, CdO, HgO, Tl₂, Ga₂O₃, In₂O₃, Bi₂O₃, Sb₂O₃, PoO₂, SeO₂, Cs₂O, La₂O₃, Pr₆O₁₁, Nd₂O₃, La₂O₃, Sm₂O₃, Eu₂O₃, Tb₄O₇, Dy₂O₃, Ho₂O₃, Er₂O₃, Tm₂O₃, Yb₂O₃, Lu₂O₃, Gd₂O₃, or a mixture thereof.

In a configuration of this embodiment, matrix (20) comprises a polymerizable or polymerized monomer or oligomer selected from:
Allyl monomers or allyl oligomers (i.e. a compound comprising an allyl group) such as for example diethylene glycol bis(allyl carbonate), ethylene glycol bis(allyl carbonate), oligomers of diethylene glycol bis(allyl carbonate), oligomers of ethylene glycol bis(allyl carbonate), bisphenol A bis(allyl carbonate), diallylphthalates such as diallyl phthalate, diallyl isophthalate and diallyl terephthalate, and mixtures thereof;
(Meth)acrylic monomers or (meth)acrylic oligomers (i.e. a compound comprising having acrylic or methacrylic groups) such as for example monofunctional (meth)acrylates or multifunctional (meth)acrylates;

Compounds used to prepare polyurethane or polythiourethane materials;

Monomer or oligomer having at least two isocyanate functions selected from symmetric aromatic diisocyanate such as 2,2′ Methylene diphenyl diisocyanate (2,2′ MD I), 4,4′ dibenzyl diisocyanate (4,4′ DBDI), 2,6 toluene diisocyanate (2,6 TDI), xylylene diisocyanate (XDI), 4,4′ Methylene diphenyl diisocyanate (4,4′ MDI) or asymmetric aromatic diisocyanate such as 2,4′ Methylene diphenyl diisocyanate (2,4′ MDI), 2,4′ dibenzyl diisocyanate (2,4′ DBDI), 2,4 toluene diisocyanate (2,4 TDI) or alicyclic diisocyanates such as Isophorone diisocyanate (IPDI), 2,5 (or 2,6)-bis(iso-cyanatomethyl)-Bicyclo[2.2.1]heptane (NDI) or 4,4′ Diisocyanato-methylenedicyclohexane (H12MD I) or aliphatic diisocyanates such as hexamethylene diisocyanate (HDI) or mixtures thereof;
Monomer or oligomer having thiol function selected from Pentaerythritol tetrakis mercaptopropionate, Pentaerythritol tetrakis mercaptoacetate, 4-Mercaptomethyl-3,6-dithia-1,8-octanedithiol, 4-mercaptomethyl-1,8-dimercapto-3,6-dithiaoctane, 2,5-dimercaptomethyl-1,4-dithiane, 2,5-bis[(2-mercaptoethyl)thiomethyl]-1,4-dithiane, 4,8-dimercaptomethyl-1,11-dimercapto-3,6,9-trithiaundecane, 4,7-dimercaptomethyl-1,11-dimercapto-3,6,9-trithiaundecane, 5,7-dimercaptomethyl-1,11-dimercapto-3,6,9-trithiaundecane and mixture thereof;
Monomer or oligomer having epithio function selected from bis(2,3-epithiopropyl)sulfide, bis(2,3-epithiopropyl)disulfide and bis[4-(beta epithiopropylthio)phenyl]sulfide, bis[4-(beta-epithiopropyloxy)cyclohexyl]sulfide.
Monomers or oligomers selected from alkoxysilanes, alkylalkoxysilanes, epoxysilanes, epoxyalkoxysilanes, and mixtures thereof.

Alkoxysilanes may be selected among compounds having the formula: RₚSi(Z)₄₋ₚ in which the R groups, identical or different, represent monovalent organic groups linked to the silicon atom through a carbon atom, the Z groups are identical or different and represent hydrolyzable groups or hydrogen atoms, p is an integer ranging from 0 to 2. Suitable alkoxysilanes may be selected in the group consisting of tetraethoxysilane Si(OC₂H₅)₄ (TEOS), tetramethoxysilane Si(OCH₃)₄ (TMOS), tetra(n-propoxy)silane, tetra(i-propoxy)silane, tetra(n-butoxy)silane, tetra(sec-butoxy)silane or tetra(t-butoxy)silane.

Alkylalkoxysilanes may be selected among compounds having the formula: RₙYₘSi(Z₁)₄₋ₙ₋ₘ in which the R groups, identical or different, represent monovalent organic groups linked to the silicon atom through a carbon atom, the Y groups, identical or different, represent monovalent organic groups linked to the silicon atom through a carbon atom, the Z groups are identical or different and represent hydrolyzable groups or hydrogen atoms, m and n are integers such that m is equal to 1 or 2 and n+m=1 or 2.

Epoxyalkoxysilanes may be selected among compounds having the formula: RₙYₘSi(Z₁)₄₋ₙ₋ₘ in which the R groups, identical or different, represent monovalent organic groups linked to the silicon atom through a carbon atom, the Y groups, identical or different, represent monovalent organic groups linked to the silicon atom through a carbon atom and containing at least one epoxy function, the Z groups are identical or different and represent hydrolyzable groups or hydrogen atoms, m and n are integers such that m is equal to 1 or 2 and n+m=1 or 2.

Suitable epoxysilanes may be selected from the group consisting of glycidoxy methyl trimethoxysilane, glycidoxy methyl triethoxysilane, glycidoxy methyl tripropoxysilane, α-glycidoxy ethyl trimethoxysilane, α-glycidoxy ethyl triethoxysilane, β-glycidoxy ethyl trimethoxysilane, β-glycidoxy ethyl triethoxysilane, β-glycidoxy ethyl tripropoxysilane, α-glycidoxy propyl trimethoxysilane, α-glycidoxy propyl triethoxysilane, α-glycidoxy propyl tripropoxysilane, β-glycidoxy propyl trimethoxysilane, β-glycidoxy propyl triethoxysilane, β-glycidoxy propyl tripropoxysilane, γ-glycidoxy propyl trimethoxysilane, γ-glycidoxy propyl triethoxysilane, γ-glycidoxy propyl tripropoxysilane, 2-(3,4-epoxycyclohexyl) ethyltrimethoxysilane, 2-(3,4-epoxycyclohexyl) ethyltriethoxysilane.

According to an embodiment, the pattern is periodic and the repetition unit of the pattern has a smallest dimension of less than 500 micrometers and comprises at least two pixels. In a particular configuration of this embodiment, the pattern is periodic in two dimensions, preferably the pattern is a rectangular lattice or a square lattice. Such periodic patterns allow for easy localization of each elementary unit on the light sensitive device, which is desirable to address absorption of each elementary unit in correspondence with an array of photosensors. In a particular configuration of this embodiment, semiconductor nanoparticles on the first pixel of the at least two pixels are different from semiconductor nanoparticles on the second pixel of the at least two pixels. In a preferred embodiment of the latter configuration, the periodic pattern comprises three pixels, one pixel being void of semiconductor nanoparticles and two pixels comprising each one type of semiconductor nanoparticles. In particular, a first pixel void of semiconductor nanoparticles, a second pixel comprising semiconductor nanoparticles with cutoff wavelength between blue range and green range and a third pixel comprising semiconductor nanoparticles with cutoff wavelength between green range and red range. By comparison of photosensor signal of these three pixels, one is able to determine red, green and blue components of light incoming on the light sensitive device. Similarly, a pattern with four pixels allows for determination of blue, green, red and infra-red components of light incoming on the light sensitive device.

The invention aims also at manufacturing light sensitive device. In order to deposit semiconductor nanoparticles on substrate, di-electrophoretic forces may be used. Said forces result in attraction of a polarizable object placed in an electric field produced by an electrically polarized surface. In addition, precision of deposition, i.e. definition of limits between areas where semiconductor nanoparticles are deposited and areas where no deposition occurs, is improved. This process is particularly suitable for patterns whose dimensions are less than 50 micrometer, preferably less than 15 micrometer, more preferably less than 10 micrometer.

Semiconductor nanoparticles of the invention are polarizable. Preferably, semiconductor nanoparticles are neutral, i.e. not charged with permanent electric charges. In particular, anisotropic semiconducting nanoparticles are subject to strong di-electrophoretic forces. So as to obtain a substrate comprising at least one photosensor, a two-step approach is preferred. Semiconductor nanoparticles are deposited on a film, then film is transferred on a photosensor sheet. The assembly of photosensor sheet and film on which semiconductor nanoparticles are deposited is the substrate of the invention.

In this embodiment, film is a soft material, for instance a polymeric material, configured to be transferred on a photosensor sheet. By transferred, it is meant any method yielding a structure comprising said soft material on the photosensor sheet. Transfer may be direct, without any material between substrate and support: this is direct contact between substrate and support. Transfer may use an adhesive between substrate and support. Transfer may use an intermediate carrier. This embodiment enables production of large pieces of film which may be stored for some time before being cut on demand and reported on photosensor sheet.

Therefore, invention also relates to a process for the manufacture of a light sensitive device comprising a substrate and semiconductor nanoparticles distributed on the substrate according to a pattern comprising the steps of:
i) Providing a film;
ii) Creating a surface electric potential on the film according to the pattern;
iii) Bringing the film in contact with a colloidal dispersion of semiconductor nanoparticles being high pass filters in UV-visible-NIR light range for a contacting time of less than 15 minutes; and
iv) Transferring film on a photosensor sheet, yielding said substrate.

The light sensitive device comprises a density of semiconductor nanoparticles per surface unit greater than 5×10⁹ nanoparticles.cm⁻².

During semiconductor nanoparticles deposition, substrate needs to be electrically polarized. This polarization may be permanent or induced.

Permanent polarization exists in materials known as electret: after application of an electric field to an electret material, a permanent electrical polarization remains. With electret material, it is possible to write a surface electric potential then to deposit semiconductor nanoparticles.

In this embodiment, the invention also relates to a process for the manufacture of a light sensitive device comprising a substrate and semiconductor nanoparticles distributed on the substrate according to a pattern comprising the following steps.

In a first step, providing an electret film. The film may be any embodiment of electret material as defined above in the detailed description of the light sensitive device of the invention. A preferred film is a film of PMMA.

In a second step, writing a surface electric potential on the electret film according to the pattern. The pattern may be any embodiment of pattern as defined above in the detailed description of the light sensitive device of the invention.

Then, in a third step, the electret film is brought in contact with a colloidal dispersion of semiconductor nanoparticles being high pass filters in UV-visible-NIR light range for a contacting time of less than 15 minutes. The resulting light sensitive device comprises a density of semiconductor nanoparticles per surface unit greater than 5×10⁹ nanoparticles.cm⁻². Due to polarization density of electret, a di-electrophoretic force is imposed to semiconductor nanoparticles which are thus attracted towards the surface. For example, with anisotropic semiconductor nanoparticles, they are eventually oriented on the surface along a predetermined direction. If semiconductor nanoparticles are larger than 25 nm, attractive forces are significant, yielding an improved deposition of semiconductor nanoparticles: deposit is denser.

Contact may be done by immersion of electret film in a colloidal dispersion of semiconductor nanoparticles, preferably in a colloidal dispersion comprising semiconductor nanoparticles in an organic solvent, more preferably in a hydrocarbon solvent such as cyclohexane, hexane, heptane, decane or pentane.

Alternatively, contact may be done by drop-casting, spin coating, pouring a colloidal dispersion of semiconductor nanoparticles on the substrate, or by micro-fluidic contact system.

Alternatively, contact may be done by spraying micrometric droplets of colloidal dispersion of semiconductor nanoparticles in a flux of gas. Due to electric polarization density of electret, a di-electrophoretic force is imposed to micrometric droplets which are thus attracted towards the surface. At the same time, drying occurs by evaporation of the solvent. As micrometric droplets are bigger than semiconductor nanoparticles, the di-electrophoretic force effect is strongly increased yielding an improved deposition of semiconductor nanoparticles. This method enables coating of large surfaces of films and improves homogeneity of deposition.

Last, in a fourth step, film is transferred on a photosensor sheet, yielding the substrate.

All features of the light sensitive device of the invention, in particular of semiconductor nanoparticles may be implemented in said process.

In a variant of this embodiment, the invention also relates to a process for the manufacture of a light sensitive device comprising a substrate and semiconductor nanoparticles distributed on the substrate according to a pattern, wherein the pattern comprises two sub-patterns comprising the following steps.

In a first step, providing an electret film. The film may be any embodiment of electret material as defined above in the detailed description of the light sensitive device of the invention. A preferred substrate is a film of PMMA.

In a second step, writing a surface electric potential on the electret film according to the first sub-pattern.

In a third step, the electret film is brought in contact with a colloidal dispersion of semiconductor nanoparticles being high pass filters in UV-visible-NIR light range for a contacting time of less than 15 minutes. The light sensitive device comprises a density of semiconductor nanoparticles per surface unit greater than 5×10⁹ nanoparticles.cm⁻².

Then, in a fourth step, electret film and semiconductor nanoparticles deposited thereon are dried to form an intermediate structure. Said intermediate structure can be treated as an electret film in the same manner as above if film surface has not been totally covered with semiconductor nanoparticles, i.e. if some surface of the electret film is still available to be electrically influenced, said surface is thus available for nanoparticles deposition.

In a fifth step, writing a surface electric potential on the intermediate structure according to the second sub-pattern.

Then, in a sixth step, the electret film is brought in contact with a colloidal dispersion of semiconductor nanoparticles being high pass filters in UV-visible-NIR light range and different from those used in step iii) for a contacting time of less than 15 minutes. The light sensitive device comprises a density of semiconductor nanoparticles per surface unit greater than 5×10⁹ nanoparticles.cm⁻².

Last, in a seventh step, film is transferred on a photosensor sheet, yielding the substrate.

In some embodiments, steps four to six may be reiterated according to a third sub-pattern, a fourth sub-pattern, without other limit than the definition of sub-patterns.

In steps three and six, contact may be done by immersion of electret film in a colloidal dispersion of semiconductor nanoparticles or by spraying micrometric droplets as described above.

Alternatively, contact may be done by drop-casting, spin coating, pouring a colloidal dispersion of semiconductor nanoparticles on the substrate, or by micro-fluidic contact system.

All features of the light sensitive device of the invention, in particular of semiconductor nanoparticles may be implemented in said process.

Besides processes using electret substrate having a permanent polarization, other processes use induced polarization.

Induced polarization corresponds to materials in which electrical polarization results from application of an external electrical field. As soon as external field is removed, electrical polarization disappears. In this case, it is possible to induce a surface electric potential and deposit semiconductor nanoparticles while surface electric potential is maintained.

In this embodiment, the invention also relates to a process for the manufacture of a light sensitive device comprising a substrate and semiconductor nanoparticles distributed on the substrate according to a pattern comprising the following steps.

In a first step, providing a film. The film may be any embodiment of substrate as defined above in the detailed description of the light sensitive device of the invention. Preferably the film is a PMMA film.

In a second step, inducing a surface electric potential on the film according to the pattern. The pattern may be any embodiment of pattern as defined above in the detailed description of the light sensitive device of the invention.

Then, in a third step, the film is brought in contact with a colloidal dispersion of semiconductor nanoparticles being high pass filters in UV-visible-NIR light range for a contacting time of less than 15 minutes, while surface electric potential is maintained. Due to polarization density of electret, a di-electrophoretic force is imposed to semiconductor nanoparticles which are thus attracted towards the surface. The resulting light sensitive device comprises a density of semiconductor nanoparticles per surface unit greater than 5×10⁹nanoparticles.cm⁻². If the semiconductor nanoparticles are anisotropic, they are eventually oriented on the surface along a predetermined direction. If semiconductor nanoparticles are larger than 25 nm, attractive forces are significant, yielding an improved deposition of semiconductor nanoparticles: deposit is denser.

Contact may be done by immersion of film in a colloidal dispersion of semiconductor nanoparticles, preferably in a colloidal dispersion comprising semiconductor nanoparticles in an organic solvent, more preferably in a hydrocarbon solvent such as cyclohexane, hexane, heptane or pentane.

Alternatively, contact may be done by drop-casting, spin coating, pouring a colloidal dispersion of semiconductor nanoparticles on the substrate, or by micro-fluidic contact system.

Alternatively, contact may be done by spraying micrometric droplets of colloidal dispersion of semiconductor nanoparticles in a flux of gas. Due to electric polarization density of substrate, a di-electrophoretic force is imposed to micrometric droplets which are thus attracted towards the surface. At the same time, drying occurs by evaporation of the solvent. As micrometric droplets are bigger than semiconductor nanoparticles, the di-electrophoretic force effect is strongly increased yielding an improved deposition of semiconductor nanoparticles. This method enables coating of large surfaces of substrate and improves homogeneity of deposition. Moreover, with a suitable calibration of the flow rate of the gas, a strong reduction of semiconductor nanoparticle solution waste and reduction of cleaning processes are obtained.

During third step, one has to simultaneously maintain surface electric potential and bring in contact film with colloidal suspension. The device used to induce surface electric potential may be located on side of the film on which semiconductor nanoparticles are deposited. Alternatively, the device used to induce surface electric potential may be located on the opposite side of the film's side on which semiconductor nanoparticles are deposited. This second configuration is preferred as contact between colloidal suspension and device used to induce surface electric potential is avoided. However, this configuration requires that film is not too thick: a thickness less than 50 μm, preferably less than 20 μm is preferred and allow improved precision of deposition.

Last, in a fourth step, film is transferred on a photosensor sheet, yielding the substrate.

All features of the light sensitive device of the invention, in particular of semiconductor nanoparticles may be implemented in said process.

In a variant of this embodiment, the invention also relates to a process for the manufacture of a light sensitive device comprising a substrate and semiconductor nanoparticles distributed on the substrate according to a pattern, wherein the pattern comprises two sub-patterns comprising the following steps.

In a first step, providing a film. The film may be any embodiment of substrate as defined above in the detailed description of the light sensitive device of the invention.

In a second step, inducing a surface electric potential on the film according to the first sub-pattern.

In a third step, the film is brought in contact with a colloidal dispersion of semiconductor nanoparticles being high pass filters in UV-visible-NIR light range for a contacting time of less than 15 minutes, while surface electric potential is maintained. The light sensitive device comprises a density of semiconductor nanoparticles per surface unit greater than 5×10⁹ nanoparticles.cm⁻².

Then, in a fourth step, film and semiconductor nanoparticles deposited thereon are dried to form an intermediate structure. Said intermediate structure can be treated as a film in the same manner as above if substrate surface has not been totally covered with semiconductor nanoparticles, i.e. if some surface of the film is still available to be electrically influenced.

In a fifth step, inducing a surface electric potential on the intermediate structure according to the second sub-pattern.

Then, in a sixth step, the film is brought in contact with a colloidal dispersion of semiconductor nanoparticles being high pass filters in UV-visible-NIR light range and different from those used in step iii) for a contacting time of less than 15 minutes, while surface electric potential is maintained. The light sensitive device comprises a density of semiconductor nanoparticles per surface unit greater than 5×10⁹ nanoparticles.cm⁻².

Last, in a seventh step, film is transferred on a photosensor sheet, yielding the substrate.

During third and sixth steps, one has to simultaneously maintain surface electric potential and bring in contact film with colloidal suspension. The device used to induce surface electric potential may be located on side of the film on which semiconductor nanoparticles are deposited. Alternatively, the device used to induce surface electric potential may be located on the opposite side of the film's side on which semiconductor nanoparticles are deposited. This second configuration is preferred as contact between colloidal suspension and device used to induce surface electric potential is avoided. However, this configuration requires that film is not too thick: a thickness less than 50 μm, preferably less than 20 μm is preferred and allow improved precision of deposition.

In some embodiments, steps four to six may be reiterated according to a third sub-pattern, a fourth sub-pattern, without other limit than the definition of sub-patterns.

In steps three and six, contact may be done by immersion of electret substrate in a colloidal dispersion of semiconductor nanoparticles or by spraying micrometric droplets as described above.

Alternatively, contact may be done by drop-casting, spin coating, pouring a colloidal dispersion of semiconductor nanoparticles on the substrate, or by micro-fluidic contact system.

All features of the light sensitive device of the invention, in particular of semiconductor nanoparticles may be implemented in said process.

Besides di-electrophoretic effect, deposition of semiconductor nanoparticles on substrate may be done by ink-jetting. Indeed, if pattern and sub-pattern dimensions are greater than 15 micrometers, preferably greater than 25 micrometers, ink-jetting provides a versatile and accurate enough method.

Therefore, invention further relates to a process for the manufacture of a light sensitive device comprising a substrate and semiconductor nanoparticles distributed on the substrate according to a pattern comprising the steps of:
i) Providing a film;
ii) Ink-jetting a colloidal dispersion of semiconductor nanoparticles being high pass filters in UV-visible-NIR light range on the film according to the pattern; and
iii) Transferring film on a photosensor sheet, yielding said substrate.

The light sensitive device comprises a density of semiconductor nanoparticles per surface unit greater than 5×10⁹ nanoparticles.cm⁻².

Alternatively, invention also relates to a process for the manufacture of a light sensitive device comprising a substrate and semiconductor nanoparticles distributed on the substrate according to a pattern comprising the steps of:
i) Providing a substrate comprising at least one photosensor; and
ii) Ink-jetting a colloidal dispersion of semiconductor nanoparticles being high pass filters in UV-visible-NIR light range on the substrate according to the pattern.

The light sensitive device comprises a density of semiconductor nanoparticles per surface unit greater than 5×10⁹ nanoparticles.cm⁻².

The invention also relates to an image sensor comprising a light sensitive device comprising a substrate and semiconductor nanoparticles distributed on the substrate according to a pattern, wherein substrate comprises at least one photosensor, wherein semiconductor nanoparticles are high pass filters in UV-visible-NIR light range, and wherein the light sensitive device comprises a density of semiconductor nanoparticles per surface unit greater than 5×10⁹ nanoparticles.cm⁻². All embodiments of the light sensitive device of the invention may be implemented in said image sensor.

While various embodiments have been described and illustrated, the detailed description is not to be construed as being limited hereto. Various modifications can be made to the embodiments by those skilled in the art without departing from the true spirit and scope of the disclosure as defined by the claims.

### BRIEF DESCRIPTION OF THE DRAWINGS

FIG. 1 illustrates an exploded view of a light sensitive device (1) comprising a substrate (2). Photosensors (3—represented by the symbol of a photodiode) are included in substrate (2). Semiconductor nanoparticles (not shown) are on the substrate (2), in the volume of pixel (4a) and (4c). Pixel (4b) is an area where light is incoming directly on photosensors (3), without being filtered: there are no nanoparticles in this pixel. Pixels (4a), (4b) and (4c) are aligned above photosensors.

FIG. 2 illustrates an anisotropic semiconductor nanoparticle, here a nanoplatelet, and defines aspect ratio.

FIG. 3 illustrates an aggregate of absorbent semiconductor nanoparticles (10), here nanoplatelets, encapsulated in a matrix (20).

FIG. 4 shows absorption spectrum (arbitrary unit) of nanoplatelets used in example 1 (cutoff about 500 nm between blue range and green range: dashed line, cutoff about 600 nm between green range and red range: dotted line and cutoff about 850 nm between visible range and Infra-red range: solid line) as a function of light wavelength (λ in nanometer).

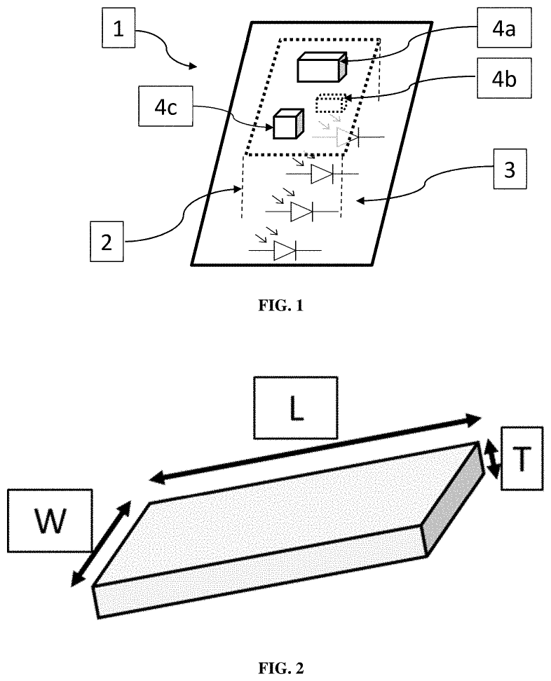

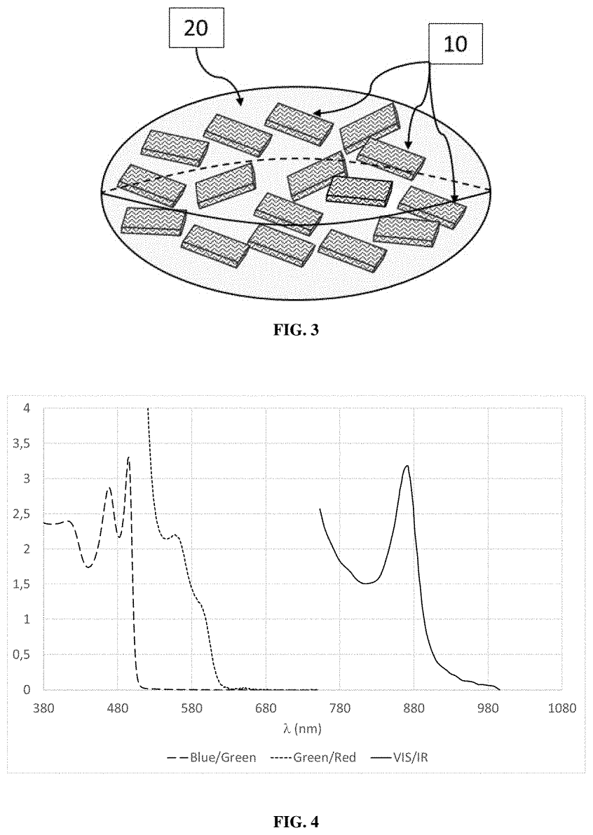

### EXAMPLES

The present invention is further illustrated by the following examples.

### Example 1

Preparation of a Stamp:

A photolithographic mask is fabricated on a UV-blue transparent substrate to reproduce a pattern with squared pixels of 5 μm size distributed on a square lattice of period 15 μm. A silicon carrier is covered by a uniform photolithography resin and illuminated by an UV lamp producing a 350 nm light filtered by the lithography mask in order to impress the pattern on the carrier. A proper washing solution for the resin is utilized to develop the polymer and create a tridimensional motif (pixelization).

A PDMS solution is casted on this tridimensional motif and the silicon carrier, then heated at 150° C. for 24 h to assure the polymerization of the PDMS. The solidified PDMS is thus separated from the silicon carrier. The so patterned PDMS is gold covered by evaporation technique to ensure a conductive pixelated surface. The patterned and conductive PDMS substrate is now called the stamp. It consists of a planar conductive surface on which square pixels of 5 μm size and 20 μm height are distributed on a square lattice. The stamp is a square of size 5 cm.

Preparation of Film:

A 20 micrometer thick PMMA solid film is used.

Preparation of Nanoparticles Colloidal Dispersions:

A solution A comprising 10⁻⁸ mole.L⁻¹ CdSe_{0.85}S_{0.15} nanoplatelets in cyclohexane is prepared. These nanoplatelets are 25 nm long, 10 nm wide and 1.2 nm thick and have a cutoff wavelength of 500 nm.

A solution B comprising 10⁻⁸ mole.L⁻¹ CdSe_{0.80}S_{0.20}/CdS nanoplatelets in cyclohexane is prepared. These nanoplatelets are 27 nm long, 12 nm wide and 5.2 nm thick (core: 1.2 nm; shell: 2 nm) and have a cutoff wavelength of 600 nm.

A solution C comprising 10⁻⁸ mole.L⁻¹ HgTe 3 monolayers nanoplatelets in cyclohexane is prepared. These nanoplatelets are 100 nm long, 200 nm wide and 1.1 nm thick and have a cutoff wavelength of 880 nm.

Absorption spectra of nanoparticles from solutions A, B and C are shown on FIG. 4.

Preparation of Light Sensitive Device and Image Sensor:

The film is put in contact with the stamp. A voltage of 50 V is applied for 1 minute in order to create permanent electrical polarization in the PMMA layer (electret material) only in correspondence with the pixels of the stamp.

To maintain stable the charges on the electret, humidity level of the environment is kept below 50%.

Electrically polarized PMMA film is dipped in solution A for 10 seconds then rinsed by a clean solvent and dried by a gentle flux of nitrogen.

Using a microscopic technique of alignment, the stamp is then again placed on the already red pixelated film, with pixels of the stamp defining a second pixel on the film (different from the blue cutting pixel) according to the original pattern chosen and in correspondence with photodiodes. A voltage of 50 V is applied again for 1 minute in order to create permanent electrical polarization in the PMMA film only in correspondence with the pixels of the stamp, i.e. in correspondence with areas free of nanoparticles.

Electrically polarized PMMA film is dipped in solution B for 10 seconds then rinsed by a clean solvent and dried by a gentle flux of nitrogen.

Using the same microscopic technique of alignment, the stamp is then again placed on the already red/green pixelated film, with pixels of the stamp defining a third pixel on the substrate (different from the blue and green cutting pixels) according to the original pattern chosen and in correspondence with photodiodes. A voltage of 50 V is applied again for 1 minute in order to create permanent electrical polarization in the PMMA film only in correspondence with the pixels of the stamp.

Electrically polarized PMMA film is dipped in solution C for 10 seconds then rinsed by a clean solvent and dried by a gentle flux of nitrogen.

The three steps are designed in such a way that an area of the film is not treated: light incoming on this area is not filtered at all.

Last, film is transferred on a photosensors sheet, so that photosensors are aligned with pixels of nanoparticles. An optically clear UV curable adhesive is used to maintain film. In addition, this adhesive provides with UV-A absorption.

An array of photodiodes coated with a 20 micrometer PMMA layer with square pixels of 5 μm size and three different types of particles (500 nm, 600 nm and 880 nm cutoff wavelength particles) distributed on a square lattice of period 15 μm is obtained, forming an light sensing device sensor suitable for measurements of visible light colour components as well as NIR component. Indeed, for each group of four photodiodes, one signal corresponds to the whole visible spectrum (UV-A filtered out by adhesive), one signal corresponds to green-red-NIR spectrum, one signal corresponds to red-NIR spectrum and one signal corresponds to NIR spectrum. By difference between signals, colour components of incoming light is therefore determined.

An image sensor is prepared with this light sensing device using well known methods of microelectronic industry.

Example 1-2

Example 1 is reproduced, except that semiconductor nanoplatelets are changed as listed in Table I.

TABLE I
Colloidal dispersions of semiconductor nanoplatelets used for deposition
on electret film (MLs refers to the number of monolayers of material).

| Nanoplatelets | Nanoplatelets dimensions | | | Cut-off λ | Deposition |
|---|---|---|---|---|---|
| / | L (nm) | W (nm) | T (nm) | / | / |
| CdSe_{0.40}S_{0.60} 5MLs | 27 | 18 | 1.5 | 500 nm | observed |
| CdSe 4MLs | 8 | 4 | 1.2 | 500 nm | observed |
| CdSe_{0.15}S_{0.85}—Br 5MLs | 30 | 20 | 1.5 | 500 nm | observed |
| CdSe 8MLs | 50 | 9 | 2.4 | 623 nm | observed |
| CdSe—Br 6MLs | 21 | 16 | 1.8 | 600 nm | observed |
| HgTe—Br 2MLs | 120 | 180 | 0.8 | 880 nm | observed |
| HgSe—Br 4MLs | 100 | 250 | 1.6 | 880 nm | observed |
| Hg_{0.50}Cd_{0.50}Te 4MLs | 120 | 200 | 1.6 | 880 nm | observed |

CORE/CROWN NANOPLATELETS

| | | | | | |
|---|---|---|---|---|---|
| CdSe/CdS 6MLs | 24 | 18 | 1.8 | 600 nm | observed |

### Example 2

Example 1 is reproduced, except that composite nanoparticles comprising absorbent nanoparticles encapsulated in a matrix are used.

Example 2-1: Absorbent Nanoplatelets in SiO₂ Matrix.

First, 500 μL of colloidal CdSe_{0.85}S_{0.15} 4 monolayers nanoplatelets in a basic aqueous solution is prepared. These nanoplatelets are 25 nm long, 10 nm wide and 1.2 nm thick and have a cutoff wavelength about 500 nm. 10 μL of a hydrolyzed basic aqueous solution of tetraethylorthosilicate (TEOS) at 0.13 mole.L⁻¹ is added to colloidal nanoplatelets and gently mixed. The liquid mixture is sprayed towards a tube furnace heated at a temperature of 300° C. with a nitrogen flow. Composite nanoparticles are collected at the surface of a filter.

A solution E comprising 10⁻⁶ mole.L⁻¹ CdSe_{0.85}S_{0.15} 4 monolayers of composite nanoparticles in heptane is prepared.

Example 2-2: Absorbent Nanoplatelets in Al₂O₃ Matrix.

First, 500 μL of colloidal CdSe_{0.85}S_{0.15} 4 monolayers nanoplatelets in heptane is prepared. These nanoplatelets are 25 nm long, 10 nm wide and 1.2 nm thick and have a cutoff wavelength about 500 nm. 5 mL of a solution of aluminium tri-sec butoxide at 0.25 mole.L⁻¹ in heptane is added to colloidal nanoplatelets and gently mixed. A basic aqueous solution is prepared separately. The two liquids are sprayed simultaneously towards a tube furnace heated at a temperature of 300° C. with a nitrogen flow. Composite nanoparticles are collected at the surface of a filter.

A solution F comprising 10⁻⁶ mole.L⁻¹ CdSe_{0.85}S_{0.15} 4 monolayers of composite nanoparticles in heptane is prepared.

Example 2-3: Absorbent Nanoplatelets in Organic Matrix.

First, 500 μL of colloidal CdSe_{0.85}S_{0.15} 4 monolayers nanoplatelets in heptane is prepared. These nanoplatelets are 25 nm long, 10 nm wide and 1.2 nm thick and have a cutoff wavelength about 500 nm. 200 mg of PMMA (PolyMethylMethAcrylate, 120 kDa) is solubilized in 10 mL of toluene, then mixed with colloidal solution. The liquid mixture was sprayed towards a tube furnace heated at 200° C. with a nitrogen flow. Composite nanoparticles are collected at the surface of a filter.

A solution G comprising 10⁻⁶ mole.L⁻¹ CdSe_{0.85}S_{0.15} 4 monolayers of composite nanoparticles in heptane is prepared.

Example 2-4: Absorbent Nanoparticles in Al₂O₃ Matrix.

First, 4 mL InP/ZnSe_{0.50}S_{0.50}/ZnS nanoparticles in heptane is prepared. These nanoparticles have a diameter of 9.5 nm (core of diameter: 3.5 nm; first shell thickness: 2 nm; second shell thickness: 1 nm) and have a cutoff wavelength about 600 nm. 5 mL of a solution of aluminium tri-sec butoxide at 0.25 mole.L⁻¹ is added to colloidal nanoplatelets and gently mixed. A basic aqueous solution is prepared separately. The two liquids are sprayed simultaneously towards a tube furnace heated at a temperature of 300° C. with a nitrogen flow. Composite nanoparticles are collected at the surface of a filter.

A solution of 50 mg of composite nanoparticles in 9 mL of tetrahydrofuran is prepared. 13 μL of octanoic acid, 60 μL of a 4-(dimethylamino)pyridine stock solution (1 mg/100 μL of dimethylformamide), 6 μL of triethylamine and 2 μL of benzoyl chloride are added. The mixture is then left to mix at room temperature over 48 hours, yielding composite nanoparticles with surface modification allowing for better dispersion in hydrocarbons solvents.

A solution H comprising 10⁻⁶ mole.L⁻¹ InP/ZnSe_{0.50}S_{0.50}/ZnS of composite nanoparticles in heptane is prepared.

Example 2-5: Absorbent Nanoparticles in Organic Matrix

First, 100 μL of InP/ZnSe_{0.50}S_{0.50}/ZnS nanoparticles in heptane is prepared. These nanoparticles have a diameter of 9.5 nm (core of diameter: 3.5 nm; first shell thickness: 2 nm; second shell thickness: 1 nm) and have a cutoff wavelength about 600 nm. 200 mg of PMMA (PolyMethylMethAcrylate, 120 kDa) is solubilized in 10 mL of toluene, then mixed with colloidal solution. The liquid mixture was sprayed towards a tube furnace heated at 200° C. with a nitrogen flow. Composite nanoparticles are collected at the surface of a filter.

A solution I comprising 10⁻⁶ mole.L⁻¹ InP/ZnSe_{0.50}S_{0.50}/ZnS of composite nanoparticles in heptane is prepared.

After dipping of electrically polarized PMMA film in solution E, F, G, H or I instead of solution A, composite nanoparticle deposition is observed as for example 1, but thickness of layer of composite nanoparticles deposited is larger than thickness of layer of non-encapsulated nanoparticles.

Example 2-6: Absorbent Nanoparticles in Matrix

Example 1 is reproduced with composite nanoparticles comprising absorbent nanoparticles encapsulated in a matrix listed in Table II.

TABLE II
Colloidal dispersions of composite particles used for deposition on electret film.

| | | | | | |
|---|---|---|---|---|---|
| | Dimensions | | Composite particle | | |
| Nanoparticles | (nm) | Matrix | dimensions | Cut-off λ | Deposition |

QUANTUM DOTS IN MATRIX

| | | | | | |
|---|---|---|---|---|---|
| InP/ZnSe_{0.50}S_{0.50}/ZnS | 7.2 | Al₂O₃ | 200 nm | 500 nm | observed |
| InP/GaP | 5 | SiO₂ | 500 nm | 500 nm | observed |
| Cd₃P₂ | 2 | PMMA | 450 nm | 500 nm | observed |
| Cd_{0.20}Zn_{0.80}Se/ZnSe/ZnS | 15 | Al₂O₃ | 150 nm | 600 nm | observed |
| CdSe/Zn_{0.50}Cd_{0.50}Se/ZnSe | 7 | SiO₂ | 350 nm | 600 nm | observed |
| InP/ZnSe | 5 | PMMA | 200 nm | 600 nm | observed |
| Ag₂S | 2 | PMMA | 250 nm | 880 nm | observed |
| Cd₃P₂/ZnS | 5 | SiO₂ | 175 nm | 880 nm | observed |
| Cd₃As₂/ZnS | 10 | Al₂O₃ | 215 nm | 880 nm | observed |

NANOPLATELETS IN MATRIX (L*W*T)

| | | | | | |
|---|---|---|---|---|---|
| CdSe_{0.40}S_{0.60} 5MLs | 27*18*1.5 | Al₂O₃ | 200 nm | 500 nm | observed |
| CdSe 4MLs | 8*4*1.2 | SiO₂ | 500 nm | 500 nm | observed |
| CdSe_{0.15}S_{0.85}—Br 5MLs | 30*20*1.5 | PMMA | 450 nm | 500 nm | observed |
| CdSe 8MLs | 50*9*2.4 | Al₂O₃ | 350 nm | 623 nm | observed |
| CdSe—Br 6MLs | 21*16*1.8 | SiO₂ | 150 nm | 600 nm | observed |
| HgTe—Br 2MLs | 120*180*0.8 | PMMA | 200 nm | 600 nm | observed |
| HgSe—Br 4MLs | 100*250*1.6 | PMMA | 215 nm | 880 nm | observed |
| Hg_{0.50}Cd_{0.50}Te 4MLs | 120*200*1.6 | SiO₂ | 175 nm | 880 nm | observed |
| CdSe_{0.40}S_{0.60} 5MLs | 27*18*1.5 | Al₂O₃ | 250 nm | 880 nm | observed |

### Example 3

Preparation of Nanoparticles Colloidal Dispersions:

A solution A comprising 10⁻⁸ mole.L⁻¹ CdSe_{0.85}S_{0.15} nanoplatelets in cyclohexane is prepared. These nanoplatelets are 25 nm long, 10 nm wide and 1.2 nm thick and have a cutoff wavelength of 500 nm.

A solution B comprising 10⁻⁸ mole.L⁻¹ CdSe_{0.80}S_{0.20}/CdS nanoplatelets in cyclohexane is prepared. These nanoplatelets are 27 nm long, 12 nm wide and 5.2 nm thick (core: 1.2 nm; shell: 2 nm) and have a cutoff wavelength of 600 nm.

A solution C comprising 10⁻⁸ mole.L⁻¹ HgTe 3 monolayers nanoplatelets in cyclohexane is prepared. These nanoplatelets are 100 nm long, 200 nm wide and 1.1 nm thick and have a cutoff wavelength of 880 nm.

Preparation of Light Sensitive Device and Image Sensor:

A sheet of photodiodes is provided. Photodiodes are distributed on 8 concentric circles of radius increasing by steps of 25 nm. Each circle being chopped in angular section of 15°, called sectors.

Solution A is ink-jetted on photodiodes corresponding to one sector. Solution B is ink-jetted on photodiodes corresponding to next sector (clockwise). Solution C is ink-jetted on photodiodes corresponding to next sector (clockwise). Next sector (clockwise) is left untreated. This process is repeated three times, yielding a circular light sensitive device of 400 micrometer diameter, with coloured sectors organized as a pie.

As four sectors have the same characteristics, this device allows for redundant analysis of signal.

### Example 4

Example 3 is reproduced, except that nanoparticles are ink-jetted on each circle so that solution A, solution B, solution C and empty are deposited successively in each sector.

### Example 5

Example 1 is reproduced, except that substrate and preparation of light sensitive device are changed.

Film is a 50 μm thick square glass slide of size 5 cm. Film is held horizontally.

The stamp is placed below the film and in contact with the substrate. A voltage of 50 V is applied in order to induce electrical polarization in the film only in correspondence with the pixels of the stamp.

While voltage is applied, a layer of solution A is poured on the top side of film and voltage is maintained for 10 seconds then shut off. Stamp is removed from bottom side of film and excess solution A is removed. Film is then rinsed by a clean solvent and dried by a gentle flux of nitrogen.

Using a microscopic technique of alignment, the stamp is then again placed below the already red pixelated film, with pixels of the stamp defining a second pixel on the film (different from the blue cutting pixel) according to the original periodic patterning chosen. A voltage of 50 V is applied in order to induce electrical polarization in correspondence with the pixels of the stamp.

While voltage is applied, a layer of solution B is poured on the top side of film and voltage is maintained for 10 seconds then shut off. Stamp is removed from bottom side of film and excess solution B is removed. Film is then rinsed by a clean solvent and dried by a gentle flux of nitrogen.

Using the same microscopic technique of alignment, the stamp is then again placed below the already red/green pixelated film, with pixels of the stamp defining a third pixel on the substrate (different from the blue and green cutting pixels) according to the original periodic patterning chosen. A voltage of 50 V is applied in order to induce electrical polarization in correspondence with the pixels of the stamp.

While voltage is applied, a layer of solution C is poured on the top side of film and voltage is maintained for 10 seconds then shut off. Stamp is removed from bottom side of film and excess solution C is removed. Film is then rinsed by a clean solvent and dried by a gentle flux of nitrogen.

Last, film is transferred on a photosensors sheet, so that photosensors are aligned with pixels of nanoparticles. An optically clear UV curable adhesive is used to maintain film.

In addition, this adhesive provides with UV-A absorption.

### Example 6

Example 5 is reproduced, but using composite nanoparticles of example 2-4 (solutions H) and example 2-5 (solutions I).

### Comparative Example C1

Example 1 is reproduced, except that nanoparticles are changed.

A solution C-A comprising 10⁻⁸ mole.L⁻¹ CdSe nanoparticles in cyclohexane is prepared. These nanoparticles are spherical (aspect ratio of 1) with a diameter of 2.5 nm and have a cutoff wavelength of 500 nm.

A solution C-B comprising 10⁻⁸ mole.L⁻¹ CdTe nanoparticles in cyclohexane is prepared. These nanoparticles are spherical (aspect ratio of 1) with a diameter of 2.5 nm have a cutoff wavelength of 600 nm.

After dipping of substrate with electrically polarized PMMA layer in solution C-A instead of solution A, no significant nanoparticle deposition is observed: isolated nanoparticles are found on the substrate, but they do not form a layer of nanoparticles. No selective deposition on the pattern occurs.

After dipping of substrate with electrically polarized PMMA layer in solution C-B instead of solution B, no significant nanoparticle deposition is observed: isolated nanoparticles are found on the substrate, but they do not form a layer of nanoparticles. No selective deposition on the pattern occurs

1.-19. (canceled)

20. A light sensitive device comprising a substrate and semiconductor nanoparticles distributed on the substrate according to a pattern, wherein substrate comprises at least one photosensor, wherein semiconductor nanoparticles are high pass filters in UV-visible-NIR light range, and wherein the light sensitive device comprises a density of semiconductor nanoparticles per surface unit greater than 5×10⁹ nanoparticles.cm⁻².

21. The light sensitive device according to claim 20, wherein semiconductor nanoparticles are deposited on the substrate with a thickness of less than 10000 nm and more than 100 nm, and the volume fraction of semiconductor nanoparticles in the light sensitive device is ranging from 10% to 90%.

22. The light sensitive device according to claim 20, wherein semiconductor nanoparticles have a longest dimension less than 1 μm.

23. The light sensitive device according to claim 20, wherein semiconductor nanoparticles are inorganic.

24. The light sensitive device according to claim 23, wherein semiconductor nanoparticles are semiconductor nanocrystals comprising a material of formula MₓQ_{y}E_{z}A_{w}, wherein: M is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs; Q is selected from the group consisting of Zn, Cd, Hg, Cu, Ag, Au, Ni, Pd, Pt, Co, Fe, Ru, Os, Mn, Tc, Re, Cr, Mo, W, V, Nd, Ta, Ti, Zr, Hf, Be, Mg, Ca, Sr, Ba, Al, Ga, In, Tl, Si, Ge, Sn, Pb, As, Sb, Bi, Sc, Y, La, Ce, Pr, Nd, Sm, Eu, Gd, Tb, Dy, Ho, Er, Tm, Yb, Cs; E is selected from the group consisting of O, S, Se, Te, C, N, P, As, Sb, F, Cl, Br, I; A is selected from the group consisting of O, S, Se, Te, C, N, P, As, Sb, F, Cl, Br, I; and x, y, z and w are independently a rational number from 0 to 5; x, y, z and w are not simultaneously equal to 0; x and y are not simultaneously equal to 0; z and w are not simultaneously equal to 0.

25. The light sensitive device according to claim 20, wherein semiconductor nanoparticles have a longest dimension greater than 25 nanometers.

26. The light sensitive device according to claim 20, wherein semiconductor nanoparticles are deposited with their longest dimension substantially aligned in a predetermined direction.

27. The light sensitive device according to claim 20, wherein nanoparticles are deposited with a thickness of less than 3000 nm and more than 200 nm.

28. The light sensitive device according to claim 20, wherein semiconductor nanoparticles have a cutoff wavelength in near infra-red range.

29. The light sensitive device according to claim 20, wherein semiconductor nanoparticles are composite nanoparticles comprising absorbent semiconductor nanoparticles encapsulated in a matrix.

30. The light sensitive device according to claim 20, wherein the pattern is periodic and the repetition unit of the pattern has a smallest dimension of less than 100 micrometers and comprises at least two pixels.

31. The light sensitive device according to claim 30, wherein the pattern is periodic in two dimensions.

32. The light sensitive device according to claim 29, wherein semiconductor nanoparticles on the first pixel of the at least two pixels are different from semiconductor nanoparticles on the second pixel of the at least two pixels.

33. A process for the manufacture of a light sensitive device comprising a substrate and semiconductor nanoparticles distributed on the substrate according to a pattern comprising the steps of:
i)providing a film;
ii) creating a surface electric potential on the film according to the pattern;
iii) bringing the film in contact with a colloidal dispersion of semiconductor nanoparticles being high pass filters in UV-visible-NIR light range for a contacting time of less than 15 minutes; and
iv) transferring film on a photosensor sheet, yielding said substrate;
wherein the light sensitive device comprises a density of semiconductor nanoparticles per surface unit greater than 5×10⁹nanoparticles.cm⁻².

34. The process for the manufacture of a light sensitive device according to claim 33, wherein the film is an electret film and the surface electric potential is written on the electret film.

35. The process for the manufacture of a light sensitive device according to claim 33, wherein the pattern comprises two sub-patterns, and wherein the process comprises:
i)providing an electret film;
ii) writing a surface electric potential on the electret film according to the first sub-pattern;
iii) bringing the electret film in contact with a colloidal dispersion of semiconductor nanoparticles being high pass filters in UV-visible-NIR light range for a contacting time of less than 15 minutes;
iv) drying the electret film and semiconductor nanoparticles deposited thereon to form an intermediate structure;
v) writing a surface electric potential on the intermediate structure according to the second sub-pattern;
vi) bringing the electret film in contact with a colloidal dispersion of semiconductor nanoparticles being high pass filters in UV-visible-NIR light range and different from those used in step iii) for a contacting time of less than 15 minutes; and
vii) transferring film on a photosensor sheet, yielding said substrate.

36. The process for the manufacture of a light sensitive device according to claim 33, wherein the surface electric potential is induced and maintained on the film during contact with colloidal dispersion.

37. The process for the manufacture of a light sensitive device according to claim 33, wherein the pattern comprises two sub-patterns, and wherein the process comprises:
i)providing a film;
ii) inducing a surface electric potential on the film according to the first sub-pattern;
iii) bringing the film in contact with a colloidal dispersion of semiconductor nanoparticles being high pass filters in UV-visible-NIR light range for a contacting time of less than 15 minutes, while surface electric potential is maintained;
iv) drying the film and semiconductor nanoparticles deposited thereon to form an intermediate structure;
v) inducing a surface electric potential on the intermediate structure according to the second sub-pattern;
vi) bringing the film in contact with a colloidal dispersion of semiconductor nanoparticles being high pass filters in UV-visible-NIR light range and different from those used in step iii) for a contacting time of less than 15 minutes, while surface electric potential is maintained; and
vii) transferring film on a photosensor sheet, yielding said substrate.

38. A process for the manufacture of a light sensitive device comprising a substrate and semiconductor nanoparticles distributed on the substrate according to a pattern comprising the steps of:
i)providing a film or a substrate comprising at least one photosensor;
ii) ink-jetting a colloidal dispersion of semiconductor nanoparticles being high pass filters in UV-visible-NIR light range on the film or substrate according to the pattern; and
iii) optionally, transferring film on a photosensor sheet, yielding a substrate comprising at least one photosensor;
wherein the light sensitive device comprises a density of semiconductor nanoparticles per surface unit greater than 5×10⁹nanoparticles.cm⁻².

39. An image sensor comprising a light sensitive device comprising a substrate and semiconductor nanoparticles distributed on the substrate according to a pattern, wherein substrate comprises at least one photosensor, wherein semiconductor nanoparticles are high pass filters in UV-visible-NIR light range, and wherein the light sensitive device comprises a density of semiconductor nanoparticles per surface unit greater than 5×10⁹ nanoparticles.cm⁻².
